(19) United States
(12) Patent Application Publication
(10) Pub. No.: US 2026/0132533 A1
(43) Pub. Date: May 14, 2026

(54) MICROELECTRONIC ARTICLES INCLUDING ELECTROPLATED METAL AND METHODS OF MAKING THE SAME

(71) Applicant: CORNING INCORPORATED, CORNING, NY (US)

(72) Inventors: Mandakini Kanungo, Ithaca, NY (US); Chukwudi Azubuike Okoro, Painted Post, NY (US); Diego Josue Prado, Bridgeport, NY (US); Robert Anthony Schaut, Horseheads, NY (US); Stanislav Sikulskyi, Corning, NY (US); Rajesh Vaddi, Horseheads, NY (US)

(21) Appl. No.: 19/362,596

(22) Filed: Oct. 20, 2025

Related U.S. Application Data
(60) Provisional application No. 63/718,212, filed on Nov. 8, 2024.

(51) Int. Cl. C25D 5/50; C25D 5/54

(52) U.S. Cl. CPC C25D 5/50; C25D 5/54

(57) ABSTRACT

A method of making a microelectronic article includes depositing at least one redistribution layer on a glass-based substrate, wherein the depositing the at least one redistribution layer includes at least one cycle of electroplating the glass-based substrate with a metal material to form an electroplated metal material, annealing the glass-based substrate and the electroplated metal material at a ramp rate greater than or equal to 0.5° C./min and less than or equal to 10° C./min to a peak temperature greater than or equal to 200° C. and less than or equal to 400° C., and disposing a dielectric material at least one of on or between the electroplated metal material. The electroplated metal material includes a hysteresis loop greater than or equal to 10,000 MPa·° C.

This application claims the benefit of priority to U.S. Provisional Patent Application Ser. No. 63/718,212 filed on Nov. 8, 2024, the content of which is relied upon and incorporated herein by reference in its entirety.

### FIELD

The present specification generally relates to microelectronic articles and, in particular, to methods of making microelectronic articles that minimize the likelihood of lateral fractures in a glass-based substrate of the microelectronic article.

### TECHNICAL BACKGROUND

Glass-based substrates are widely used in microelectronic articles due to attributes such as low dielectric constant, high rigidity, and panel size capability. The glass-based substrates used in microelectronics include an overlay of multiple layers of metal and dielectric materials, referred to as redistribution layers (“RDLs”). The buildup of the RDLs and the differences in coefficient of thermal expansion (“CTE”) and elastic modulus between the glass-based substrate and the RDLs may induce stresses that are transferred to the glass-based substrate, resulting in lateral fractures. Conventionally, glass-based substrates with a high CTE may be used to minimize the CTE mismatch between the RDLs and glass-based substrate. However, this limits the glass-based substrates that can be used in these microelectronic articles.

Therefore, a continuing need exists for methods of making microelectronic articles that minimize the likelihood of lateral fractures in a glass-based substrate of the microelectronic article, regardless of the CTE of the glass-based substrate.

### SUMMARY

According to a first aspect A1, a method of making a microelectronic article comprises: depositing at least one redistribution layer on a glass-based substrate, wherein the depositing the at least one redistribution layer comprises at least one cycle of: electroplating the glass-based substrate with a metal material to form an electroplated metal material;

annealing the glass-based substrate and the electroplated metal material at a ramp rate greater than or equal to 0.5° C./min and less than or equal to 10° C./min to a peak temperature greater than or equal to 200° C. and less than or equal to 400° C.; and disposing a dielectric material at least one of on or between the electroplated metal material, wherein the electroplated metal material comprises a hysteresis loop greater than or equal to 10,000 MPa·° C.

According to a second aspect A2, a method of making a microelectronic article comprises: depositing at least one redistribution layer on a glass-based substrate, wherein the depositing the at least one redistribution layer comprises at least one cycle of: electroplating the glass-based substrate with a metal material to form an electroplated metal material, wherein the electroplated metal material has an impurity content of less than or equal to 1000 parts per million by weight (ppmw); and disposing a dielectric material at least one of on or between the electroplated metal material, wherein the electroplated metal material comprises a hysteresis loop greater than or equal to 10,000 MPa·° C.

According to a third aspect A3, a method of making a microelectronic article comprises: depositing at least one redistribution layer on a glass-based substrate, wherein the depositing the at least one redistribution layer comprises at least one cycle of: electroplating the glass-based substrate with a metal material to form an electroplated metal material, wherein electroplating occurs at a current density of greater than or equal to 0.1 mA/cm²; and disposing a dielectric material at least one of on or between the electroplated metal material, wherein the electroplated metal material comprises a hysteresis loop greater than or equal to 10,000 MPa·° C.

A fourth aspect A4 includes the method of any one of the first through third aspects A1-A3, wherein the metal material comprises copper, aluminum, aluminum-copper, or a combination thereof.

A fifth aspect A5 includes the method of any one of the first through fourth aspects A1-A4, wherein the glass-based substrate comprises a first surface and a second surface opposite the first surface, the at least one redistribution layer being deposited on each of the first surface and the second surface.

A sixth aspect A6 includes the method of the fifth aspect A5, wherein the at least one redistribution layer comprises a first redistribution layer disposed on the first surface of the glass-based substrate and a second redistribution layer disposed on the second surface of the glass-based substrate, the first redistribution layer being different than the second redistribution layer.

A seventh aspect A7 includes the method of any one of the first through sixth aspects A1-A6, wherein the method further comprises, prior to the depositing the at least one redistribution layer, disposing an adhesion promoter on the glass-based substrate.

An eighth aspect A8 includes the method of any one of the first through seventh aspects A1-A7, wherein the method further comprises forming a through glass via in the glass-based substrate.

A ninth aspect A9 includes the method of the eighth aspect A8, wherein the method further comprises disposing the metal material in the through glass via.

A tenth aspect A10 includes the method of the any one of the first through ninth aspects A1-A9, wherein the dielectric material comprises polyimide, polybenzoxazoles, polyolefin, polystyrene, epoxy resins, parylene, benzocyclobutene, ring-opened norbornen type polymers, or combinations thereof.

An eleventh aspect A11 includes the method of the any one of the first through tenth aspects A1-A10, wherein the glass-based substrate has a coefficient of thermal expansion greater than or equal to 0.2×10⁻⁶/° C. and less than or equal to 13×10⁻⁶/° C.

A twelfth aspect A12 includes the method of the any one of the first through eleventh aspects A1-A11, wherein the electroplated metal material comprises a yield stress less than 200 MPa.

According to a thirteenth aspect A13, a microelectronic article comprises: a glass-based substrate and at least one redistribution layer disposed on the glass-based substrate, wherein: the redistribution layer comprises an electroplated metal material and a dielectric material; and the electroplated metal material comprises a hysteresis loop greater than or equal to 10,000 MPa·° C.

A fourteenth aspect A14 includes the microelectronic article of the thirteenth aspect A13, wherein the redistribution layer further comprises an adhesion promoter.

A fifteenth aspect A15 includes the microelectronic article of the thirteenth aspect A13 or the fourteenth aspect A14, wherein the electroplated metal material comprises copper, aluminum, aluminum-copper, or a combination thereof.

A sixteenth aspect A16 includes the microelectronic article of any one of the thirteenth through fifteenth aspects A13-A15, wherein the electroplated metal material is patterned.

A seventeenth aspect A17 includes the microelectronic article of any one of the thirteenth through sixteenth aspects A13-A16, wherein the dielectric material comprises polyimide, polybenzoxazoles, polyolefin, polystyrene, epoxy resins, parylene, benzocyclobutene, ring-opened norbornen type polymers, or combinations thereof.

An eighteenth aspect A18 includes the microelectronic article of any one of the thirteenth through seventeenth aspects A13-A17, wherein the microelectronic article further comprises a metallized through glass via.

A nineteenth aspect A19 includes the microelectronic article of any one of the thirteenth through eighteenth aspects A13-A18, wherein the glass-based substrate comprises a first surface and a second surface; a first redistribution layer disposed on the first surface; and a second redistribution layer disposed on the second surface.

A twentieth aspect A20 includes the microelectronic article of any one of the thirteenth through nineteenth aspects A13-A19, wherein the at least one redistribution layer comprises greater than or equal to 2 and less than or equal to 10 layers of the electroplated metal material, each of the layers of the electroplated material comprising a thickness greater than or equal to 0.5 μm and less than or equal to 25 μm.

A twenty-first aspect A21 includes the microelectronic article of any one of the thirteenth through twentieth aspects A13-A20, wherein the electroplated metal material comprises a yield stress less than 200 MPa.

A twenty-second aspect A22 includes the microelectronic article of any one of the thirteenth through twenty-first aspects A13-A21, wherein the microelectronic article comprises a warp less than or equal to 50 μm, as measured at an edge of the microelectronic article, when the microelectronic article is 50 mm by 50 mm.

A twenty-third aspect A23 includes the microelectronic article of any one of the thirteenth through twenty-second aspects A13-A22, wherein the metal material comprises an impurity content less than or equal to 1000 ppmw.

A twenty-fourth aspect A24 includes the microelectronic article of any one of the thirteenth through twenty-third aspects A13-A23, wherein the glass-based substrate has a coefficient of thermal expansion greater than or equal to 0.2×10⁻⁶/° C. and less than or equal to 13×10⁻⁶/° C.

A twenty-fifth aspect A25 includes the microelectronic article of any one of the thirteenth through twenty-fourth aspects A13-A24, wherein the glass-based substrate comprises a thickness greater than or equal to 100 μm and less than or equal to 1000 μm.

A twenty-sixth aspect A26 includes the microelectronic article of any one of the thirteenth through twenty-fifth aspects A13-A25, wherein the at least one redistribution layer comprises a thickness greater than or equal to 500 nm.

Additional features and advantages of the microelectronic articles and methods of making same described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is a schematic view of a microelectronic article, according to embodiments described herein;

FIG. 2A is a schematic view of a comparative microelectronic article;

FIG. 2B is a schematic view of an exemplary microelectronic article, according to embodiments described herein;

FIG. 3 is a plot of temperature (y-axis; in degrees Celsius (° C.)) versus time (x-axis; in hours (hrs)) of electroplated copper thermal cycling, according to embodiments described herein;

FIG. 4A is a plot of biaxial stress of (y-axis; in MPa) of an electroplated metal material versus temperature (x-axis; in ° C.) of an exemplary microelectronic article, according to embodiments described herein;

FIG. 4B is a plot of biaxial stress (y-axis; in MPa) of an electroplated metal material versus temperature (x-axis; in ° C.) of an exemplary microelectronic article, according to embodiments described herein;

FIG. 5 is a graph of hysteresis loop area (y-axis; in MPa·° C.) for the first, second, and third cycles of the electroplated metal material of exemplary microelectronic articles, according to embodiments described herein;

FIG. 6A is a plot of biaxial stress (y-axis; in MPa) of an electroplated metal material versus temperature (x-axis; in ° C.) of a comparative microelectronic article;

FIG. 6B is a plot of biaxial stress (y-axis; in MPa) of an electroplated metal material versus temperature (x-axis; in ° C.) of an exemplary microelectronic article, according to embodiments described herein;

FIG. 7 is a graph of hysteresis loop area (y-axis; in MPa·° C.) for the first, second, and third cycles of the electroplated metal material of a comparative microelectronic article and an exemplary microelectronic article, according to embodiments described herein;

FIG. 8A is a schematic view of an exemplary microelectronic article, according to embodiments described herein;

FIG. 8B is a depiction of warp output on the microelectronic article of FIG. 8A;

FIG. 8C is a plot of warp at the edges of the glass (y-axis; in micrometers (μm)) versus zero-stress (c) temperature of plated copper (Cu) (x-axis; in ° C.) of the microelectronic article of FIG. 8A;

FIG. 9A is a schematic view of an exemplary microelectronic article, according to embodiments described herein;

FIG. 9B is a plot of location at edge (y-axis; in mm) versus stress (x-axis; in MPa) for variable yield stress and zero-stress temperatures;

FIG. 10A is a plot of peak stress (y-axis; in MPa) versus zero-stress temperature of the plated copper (x-axis; in ° C.);

FIG. 10B is a plot of midplane stress (y-axis; in MPa) versus zero-stress temperature of the plated copper (x-axis; in ° C.); and

FIG. 11 is a model of a plastic strain distribution in an exemplary microelectronic article, according to embodiments described herein.

### DETAILED DESCRIPTION

Reference will now be made in detail to various embodiments of microelectronic articles and methods for making microelectronic articles having a decreased likelihood for glass fractures, regardless of the CTE of a glass-based substrate included in the microelectronic article.

According to embodiments, a method of making a microelectronic article includes depositing at least one redistribution layer on a glass-based substrate. Depositing the at least one redistribution layer includes at least one cycle of electroplating the glass-based substrate with a metal material to form an electroplated metal material, annealing the glass-based substrate and the electroplated metal material at a ramp rate greater than or equal to 0.5° C./min and less than or equal to 10° C./min to a peak temperature greater than or equal to 200° C. and less than or equal to 400° C., and disposing a dielectric material at least one of on or between the electroplated metal material. The electroplated metal material includes a hysteresis loop greater than or equal to 10,000 MPa·° C.

According to embodiments, a method of making a microelectronic article includes depositing at least one redistribution layer on a glass-based substrate. Depositing the at least one redistribution layer includes at least one cycle of electroplating the glass-based substrate with a metal material to form an electroplated metal material, wherein the electroplated metal material has an impurity content of less than or equal to 1000 parts per million by weight (ppmw), and disposing a dielectric material at least one of on or between the electroplated metal material. The electroplated metal material includes a hysteresis loop greater than or equal to 10,000 MPa·° C.

According to embodiments, a method of making a microelectronic article includes depositing at least one redistribution layer on a glass-based substrate. Depositing the at least one redistribution layer includes at least one cycle of electroplating the glass-based substrate with a metal material to form an electroplated metal material, wherein electroplating occurs at a current density of greater than or equal to 0.1 mA/cm², and disposing a dielectric material at least one of on or between the electroplated metal material. The electroplated metal material includes a hysteresis loop greater than or equal to 10,000 MPa·° C.

According to embodiments, a microelectronic article includes a glass-based substrate and at least one redistribution layer disposed on the glass-based substrate. The redistribution layer includes an electroplated metal material and a dielectric material. The electroplated metal material includes a hysteresis loop greater than or equal to 10,000 MPa·° C.

Various embodiments of microelectronic articles and methods of making the same will be described herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural referents unless the context clearly dictates otherwise. Thus, for example, reference to “a” component includes aspects having two or more such components, unless the context clearly indicates otherwise.

“Glass-based substrate,” as described herein, refers to a substrate that comprises amorphous glass or glass-ceramics. The term “glass-ceramic” may refer to solids prepared by controlled crystallization of a precursor glass and have one or more crystalline phases and a residual amorphous glass phase.

“Dispose,” as described herein, refers to any coating, depositing, and/or forming of a material onto a surface using any known method in the art. The disposed material may constitute a layer, as described herein. The phrase “disposed on” may include the instance of forming or depositing a material onto a surface such that the material is in direct contact with the surface and also may include the instance where the material is formed or deposited on a surface, with one or more intervening materials between the disposed material and the surface. The intervening materials may constitute a layer, as described herein.

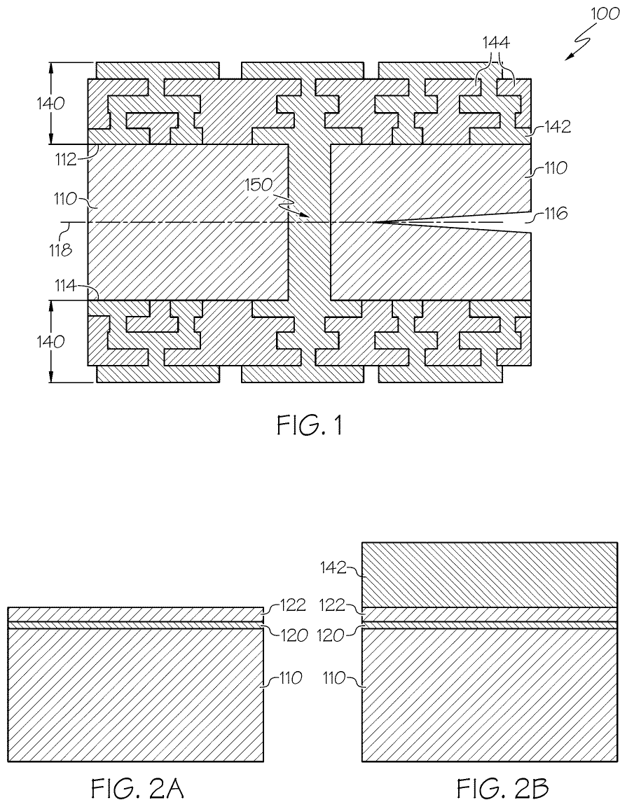

A “layer,” as described herein, refers to a sheet of a material that has generally even thickness covering a surface. A “redistribution layer” (RDL) may refer to the layer comprising dielectric and metal materials that make up an integrated circuit of a microelectronic article, as known by those skilled in the art. In some embodiments, a redistribution layer may be “integrated” such that the dielectric material and the metal material present in the redistribution layer are joined in an intertwined manner, such as, for example, in FIG. 1. In such embodiments, the dielectric material may be etched, lasered, or otherwise modified to create gaps that are filled with metal material, and vice versa. This process, described further herein, may result in an “integrated” redistribution layer.

“Coefficient of thermal expansion” (CTE), as described herein, is measured by thermomechanical analysis (TMA), which is a technique used to measure how a material deforms over time or temperature while under a constant force. TMA was performed herein following ASTM E831-24.

“Warp,” as described herein, refers to the difference between the highest and lowest point of a substrate. As used herein, “warp” is measured as the difference between the highest and lowest point measured at 5 millimeters (mm) from an edge of the glass-based substrate.

“Yield stress”, as described herein, is the stress corresponding to the yield point at which a material begins to deform plastically. Yield stress/strength is measured by following the procedure laid out in ASTM E8/E8M-24.

A “hysteresis loop” represents the amount of dissipated energy produced in a material by an application of a cyclic loading. It indicates the amount of inelastic deformation in a material. Under the same conditions, a larger hysteresis loop correlates with lower elastic film stresses and lower material yield strength, which means a reduced risk of reliability failures of a glass-based substrate. A hysteresis loop value is determined by calculating the area within a loop of a stress-temperature curve and is used herein as a metric for assessing reliability. The stress-temperature curve is achieved using a FLX2320-S measurement system from Toho Technology. This system uses a laser to scan across the length of a sample having a coating (e.g., Cu) on one side of a glass-based substrate and records the angle of reflection at 50 scan points. From the change in the angle of reflectance across the sample, a single value for the radius of curvature (R) is calculated for each scan. During the thermal cycling, the laser scanner performs an in-situ measurement of the radius of curvature (R) of the sample, as a function of temperature. By knowing the coating thickness (t_{f}), substrate biaxial modulus (Mₛ) and substrate thickness (tₛ), coating stress (σ_{f}) was determined by the system using the Stoney equation, shown in Formula I, where R₂ is the curvature of the coated sample at a particular temperature and R₁ is the curvature of the glass-based substrate before coating deposition. Although a hysteresis loop area is measured on a substrate with one-sided coating, a substrate with two-sided coating has a substantially similar stress on each side of coating.

$${σ}_{f} = \frac{{M}_{s}}{6} \frac{{t}_{s}^{2}}{{t}_{g}} ( \frac{1}{{R}_{2}} - \frac{1}{{R}_{1}} ) \qquad ( I )$$

Referring now to FIG. 1, a microelectronic article is shown at 100. The microelectronic article 100 may comprise a glass-based substrate 110 comprising a first surface 112 and a second surface 114 opposite the first surface 112. At least one redistribution layer (RDL) 140 may be disposed on the first surface 112 and the second surface 114. The RDLs 140 may comprise a metal material 142 and a dielectric material 144. The metal material 142 and the dielectric material 144 may be integrated in the RDLs 140. The microelectronic article 100 may further comprise a through glass via 150. The through glass via 150 may be an aperture that extends from the first surface 112 to the second surface 114. The through glass via 150 may comprise the metal material 142 such that the metal material 142 serves as an electrical interconnect through the microelectronic article 100. In some embodiments, the metal material 142 may be disposed in the through glass via 150 prior to formation of the redistribution layers 140. The formation process of the microelectronic article 100 is described further herein. Without being bound by any particular theory, the redistribution layers 140 may cause stress buildup in the glass-based substrate 110, especially in the first surface 112 and the second surface 114. The stresses may be caused by property mismatches of the different materials in the microelectronic article 100, such as a mismatch between the coefficients of thermal expansion and/or elastic modulus of the metal material 142 and the glass-based substrate 110. These stresses may build up in the RDLs 140 and may be transferred to the glass-based substrate 110. Since the glass-based substrate 110 is unable to deform due to the rigidity of the RDLs 140, the stresses may result in lateral fractures 116 in the glass-based substrate 110. Conventionally, glass-based substrates with a high CTE may be used to minimize the CTE mismatch between the redistribution layers and glass-based substrate. However, this limits the glass-based substrates that can be used in these microelectronic articles.

Disclosed herein are methods of making microelectronic articles that mitigate the aforementioned problems. Specifically, methods of making the microelectronic articles described herein include using an electroplated metal material that has a relatively high hysteresis loop area (e.g., greater than or equal to 10,000 MPa·° C.). The relatively high hysteresis loop area may be achieved in various ways, such as given annealing conditions, electroplating impurity levels, and/or electroplating current density. The resulting electroplated metal material with a relatively high hysteresis loop area thereby transfers a relatively low amount of stress to the glass-based substrate and minimizes the likelihood of lateral fractures in the glass-based substrate, regardless of the CTE of the glass-based substrate.

Referring again to FIG. 1, the method of making a microelectronic article 100 may include depositing at least one redistribution layer 140 on a glass-based substrate 110. Depositing the at least one distribution layer 140 may comprise at least one cycle of electroplating the glass-based substrate 110 with a metal material 142 to form an electroplated metal material 142, annealing the glass-based substrate 110 and the electroplated metal material 142 at a ramp rate greater than or equal to 0.5° C./min and less than or equal to 10° C./min to a peak temperature greater than or equal to 200° C. and less than or equal to 400° C. and disposing a dielectric material 144 at least one of on or between the metal material 142. The resulting microelectronic article may comprise a hysteresis loop greater than or equal to 10,000 MPa·° C.

The at least one redistribution layer 140 may comprise the metal material 142 and the dielectric material 144. The metal material 142 and the dielectric material 144 may be disposed on the glass-based substrate in layers. The metal material 142 and the dielectric material 144 may be integrated, such that the two materials are joined in an intertwined manner. The metal material 142 and the dielectric material 144 may be integrated during the formation process of the microelectronic article 100.

As stated, the redistribution layer 140 may be formed (i.e., deposited on the glass-based substrate 110) by at least one cycle of electroplating the metal material 142 on the glass-based substrate 110, annealing the glass-based substrate 110 and the electroplated metal material 142, and disposing a dielectric material 144 at least one of on or between the metal material 142. Depositing the redistribution layer 140 on the glass-based substrate 110 may comprise multiple of these cycles. For example, depositing the at least one redistribution layer 140 on the glass-based substrate 110 may comprise at least two, at least three, at least four, at least five, at least six, at least seven, at least eight, at least nine, or at least ten cycles.

After electroplating and annealing, the metal material 142 may then be chemically etched or patterned resulting in gaps with no metal material 142 present. The dielectric material 144 may be disposed on the patterned metal material 142 such that the dielectric material 144 fills the gaps in the metal material 142 while simultaneously forming on top of the patterned metal material 142. The same process may be employed on the dielectric material 144 of chemical etching or patterning creating gaps in the dielectric material 144, disposing metal material 142 to fill the gaps in the dielectric material 144 with the formation of metal material 142 disposed on the newly formed dielectric material 144. The process may be subsequently repeated with the metal material 142 and the dielectric material 144 to build up the desired thickness and makeup of the redistribution layer 140. This process may create the “integrated” redistribution layer 140 wherein the metal material 142 and the dielectric material 144 are joined in an intertwined, or interlocked, manner, as shown in FIG. 1. Additionally, as shown in FIG. 1, in some embodiments, the redistribution layers 140 may be symmetric with respect to the mid-plane 118 of the glass-based substrate 110, wherein each redistribution layer 140 may comprise the metal material 142 and the dielectric material 144 in the same disposal order and/or same etched pattern reflected across the mid-plane 118. In other embodiments (not shown), the redistribution layers 140 may not be symmetric with respect to the mid-plane 118.

In embodiments, the at least one redistribution layer 140 may have a thickness of at least 500 nm. For example, the at least one redistribution layer 140 may have a thickness of at least 520 nm, at least 540 nm, at least 560 nm, at least 580 nm, at least 600 nm, at least 560 nm, at least 570 nm, at least 580 nm, at least 590 nm, at least 600 nm.

The glass-based substrate 110 may comprise a first surface 112 and a second surface 114 opposite the first surface 112. While not wishing to be bound by theory, the glass composition of the glass-based substrate, and properties thereof (e.g., CTE), may have minimal effect on the resulting hysteresis loop area. The glass-based substrate 110 may comprise silicate glass, an aluminosilicate glass, alkali aluminosilicate glass, alkaline earth aluminosilicate glass, borosilicate glass, boro-aluminosilicate glass, alkali aluminoborosilicate glass, alkaline earth aluminoborosilicate glass, soda-lime glass, or fused quartz (fused silica). Example commercial glass substrates include, but are not limited to, HPFS® ArF Grade Fused Silica sold by Corning Incorporated of Corning, New York under glass codes 7980, 7979, and 8655; Corning carrier glasses sold by Corning Incorporated of Corning, New York under glass codes SG3.4, SG7.8, and SG9.0; and Corning® EAGLE XG® Glass, e.g., boro-aluminosilicate glass also sold by Corning Incorporated of Corning, New York. Other glass substrates include, but are not limited to, Corning Lotus™ NXT Glass, Corning Iris™ Glass, Corning® WILLOW® Glass, Corning® Gorilla® Glass, Corning VALOR® Glass, or PYREX® Glass sold by Corning Incorporated of Corning, New York. Other glass compositions are contemplated.

In embodiments, by way of example and not limitation, the glass-based substrate 110 may comprise greater than or equal to 55 mol % and less than or equal to 75 mol % SiO₂, greater than or equal to 5 mol % and less than or equal to 20 mol % Al₂O₃, greater than or equal to 0.5 mol % and less than or equal to 15 mol % B₂O₃, greater than or equal to 0 mol % and less than or equal to 20 mol % Na₂O, greater than or equal to 0 mol % and less than or equal to 1 mol % K₂O, greater than or equal to 0.5 mol % and less than or equal to 5 mol % MgO, greater than or equal to 0 mol % and less than or equal to 15 mol % CaO, greater than or equal to 0 mol % and less than or equal to 2 mol % SrO, greater than or equal to 0 mol % and less than or equal to 1 mol % SnO₂, and greater than or equal to 0 mol % and less than or equal to 1 mol % Fe₂O₃.

In some embodiments, one redistribution layer 140 may be deposited on either the first surface 112 or the second surface 114. In other embodiments, the at least one redistribution layer 140 may be deposited on each of the first surface 112 and the second surface 114 as shown in FIG. 1. In such embodiments, the at least one redistribution layer 140 may comprise a first redistribution layer disposed on the first surface 112 of the glass-based substrate 110 and a second redistribution layer disposed on the second surface 114 of the glass-based substrate 110. The first distribution layer may be different from the second redistribution layer. As a non-limiting example, the first redistribution layer may have a different disposal sequence of metal material 142 and dielectric material 144 than the second redistribution layer. In other embodiments, the first redistribution layer may have a different chemical etching or patterning of the metal material 142 and/or the dielectric material 144 than the second redistribution layer.

The metal material 142 may comprise copper, aluminum, aluminum-copper, or a combination thereof. The metal material 142 may be electroplated on the glass-based substrate 110 to form an electroplated metal material 142. In embodiments, the electroplated metal material 142 may have an impurity content less than or equal to 1000 parts per million by weight (ppmw) to ensure that an electroplated metal material having a relatively high hysteresis loop area (e.g., greater than or equal to 10,000 MPa·° C.) is achieved. For example, the metal material 142 may have an impurity content less than or equal to 950 ppmw, less than or equal to 900 ppmw, less than or equal to 850 ppmw, less than or equal to 800 ppmw, less than or equal to 750 ppmw, less than or equal to 700 ppmw, less than or equal to 650 ppmw, less than or equal to 600 ppmw, less than or equal to 550 ppmw, less than or equal to 500 ppmw, less than or equal to 450 ppmw, less than or equal to 400 ppmw, less than or equal to 350 ppmw, less than or equal to 300 ppmw, less than or equal to 250 ppmw, or less than or equal to 200 ppmw.

The glass-based substrate 110 and the electroplated metal material 142 may undergo an annealing process, which may comprise heating the glass-based substrate 110 and the electroplated metal material 142 to a certain peak temperature at a certain ramp rate to achieve a relatively high hysteresis loop area (e.g., greater than or equal to 10,000 MPa·° C.). The glass-based substrate 110 and the electroplated metal material 142 may be annealed at a ramp rate greater than or equal to 0.5° C./min and less than or equal to 10° C./min to ensure that an electroplated metal material having a relatively high hysteresis loop area (e.g., greater than or equal to 10,000 MPa·° C.) is achieved. For example, in some embodiments, the ramp rate may be greater than or equal to 1° C./min, greater than or equal to 2° C./min, greater than or equal to 3° C./min, greater than or equal to 4° C./min, greater than or equal to 5° C./min, greater than or equal to 6° C./min, greater than or equal to 7° C./min, greater than or equal to 8° C./min, greater than or equal to 9° C./min, and less than or equal to 9° C./min, less than or equal to 8° C./min, less than or equal to 7° C./min, less than or equal to 6° C./min, less than or equal to 5° C./min, less than or equal to 4° C./min, less than or equal to 3° C./min, less than or equal to 2° C./min, less than or equal to 1° C./min, or any and all sub-ranges formed from any of these endpoints.

The glass-based substrate 110 and the electroplated metal material 142 may be annealed to a peak temperature greater than or equal to 200° C. and less than or equal to 400° C. to ensure that an electroplated metal material having a relatively high hysteresis loop area (e.g., greater than or equal to 10,000 MPa·° C.) is achieved. For example, the peak temperature may be greater than or equal to 220° C., greater than or equal to 240° C., greater than or equal to 260° C., greater than or equal to 280° C., greater than or equal to 300° C., greater than or equal to 320° C., greater than or equal to 340° C., greater than or equal to 360° C., greater than or equal to 380° C. and less than or equal to 380° C., less than or equal to 360° C., less than or equal to 340° C., less than or equal to 320° C., less than or equal to 300° C., less than or equal to 280° C., less than or equal to 260° C., less than or equal to 240° C., less than or equal to 220° C., or any and all sub-ranges formed from any of these endpoints.

In embodiments, the metal material 142 may be electroplated onto the glass-based substrate 110 at a current density greater than or equal to 0.1 milliAmps/square centimeters (mA/cm²) to ensure that an electroplated metal material having a relatively high hysteresis loop area (e.g., greater than or equal to 10,000 MPa·° C.) is achieved. For example, in embodiments, the current density may be greater than or equal to 0.2 mA/cm², greater than or equal to 0.3 mA/cm², greater than or equal to 0.4 mA/cm², greater than or equal to 0.5 mA/cm², greater than or equal to 0.6 mA/cm², greater than or equal to 0.7 mA/cm², greater than or equal to 0.8 mA/cm², greater than or equal to 0.9 mA/cm², greater than or equal to 1 mA/cm², greater than or equal to 1.2 mA/cm², greater than or equal to 1.4 mA/cm², greater than or equal to 1.6 mA/cm², greater than or equal to 1.8 mA/cm², greater than or equal to 2 mA/cm², greater than or equal to 2.2 mA/cm², greater than or equal to 2.4 mA/cm², greater than or equal to 2.6 mA/cm², greater than or equal to 2.8 mA/cm², or greater than or equal to 3 mA/cm².

Without being bound by any particular theory, it is believed that one or more of electroplating the glass-based substrate 110 to form an electroplated metal material 142 comprising an impurity content of less than 1000 ppmw, electroplating at a current density of greater than 0.1 mA/cm², and annealing the glass-based substrate 110 to a peak temperature of greater than or equal to 200° C. to less than or equal to 400° C. at a ramp rate of greater than or equal to 0.5° C./min and less than or equal to 10° C./min may, in any combination or separately, ensure that the electroplated metal material 142 comprises a hysteresis loop of greater than or equal to 10,000 MPa·° C.

Referring now to FIG. 2B, an exemplary schematic view of a microelectronic article 100 is shown, as described herein. In embodiments, prior to the depositing of the at least one redistribution layer 140, an adhesion promoter 120 may be disposed on the glass-based substrate 110. The adhesion promoter 120 may comprise titanium, titanium nitride, tantalum, tantalum nitride, chromium, titanium-tungsten, solution-based systems (vitrocoat, polyimide).

Still referring to FIG. 2B, in embodiments, prior to the depositing of the at least one redistribution layer 140, a layer of sputtered copper 122 may be disposed onto the glass-based substrate 110 or the adhesion promoter 120. The layer of copper 122 may be disposed through a sputtering process, which refers to an electronic process that uses a metal target in a vacuum to deposit thin films of metal onto surfaces.

In embodiments, a through glass via 150 may be formed in the glass-based substrate 110. The through glass via 150 may extend through the glass-based substrate 110 from the first surface 112 to the second surface 114. The through glass via 150 may be formed by chemical etching and/or laser damaging the glass-based substrate 110. After cleaning the glass-based substrate 110, a channel extending the through glass via 150 may be formed in glass-based substrate 110 by chemical etching and/or laser damage. The metal material 142 may be disposed in the through glass via 150 to form a metallized through glass via 150, as shown in FIG. 1. As used herein, a “metallized through glass via” may refer to a through glass via that comprises the metal material 142. In some embodiments, metal material 142 may be introduced into the through glass via 150. In embodiments, the metal material 142 may completely fill the through glass via 150. In one or more embodiments, the metal material 142 may coat the surfaces of the through glass via 150. The metallized through glass via 150 may serve as an electric connection through the microelectronic article 100.

The dielectric material 144 may comprise polyimide, polybenzoxazoles, polyolefin, polystyrene, epoxy resins, parylene, benzocyclobutene, ring-opened norbornen type polymers, or combinations thereof. In embodiments, the dielectric material may be photo-patternable polyimide.

As described herein, a microelectronic article 100 may comprise a glass-based substrate 110 and at least one redistribution layer 140 disposed on the glass-based substrate 110. The redistribution layer 140 may comprise an electroplated metal material 142 and a dielectric material 144.

The electroplated metal material 142 may comprise a hysteresis loop greater than or equal to 10,000 MPa·° C. In embodiments, the electroplated metal material 142 may comprise a hysteresis loop greater than or equal to 10,500 MPa·° C., greater than or equal to 11,000 MPa·° C., greater than or equal to 11,500 MPa° C., greater than or equal to 12,000 MPa·° C., greater than or equal to 12,500 MPa·° C., greater than or equal to 13,000 MPa·° C., greater than or equal to 13,500 MPa·° C., greater than or equal to 14,000 MPa·° C., greater than or equal to 14,500 MPa·° C., greater than or equal to 15,000 MPa·° C., greater than or equal to 15,500 MPa·° C., or greater than or equal to 16,000 MPa·° C. In embodiments, the electroplated metal material 142 may comprise a hysteresis loop from 10,500 MPa·° C. to 16,000 MPa·° C., from 11,000 MPa·° C. to 15,500 MPa·° C., from 11,500 MPa·° C. to 15,000 MPa·° C., from 12,000 MPa·° C. to 14,500 MPa·° C., from 12,500 MPa·° C. to 14,000 MPa·° C., from 13,000 MPa·° C. to 14,000 MPa·° C., or any and all sub-ranges formed from any of these endpoints. Without being bound by any particular theory, a hysteresis loop greater than or equal to 10,000 MPa·° C. indicates that the electroplated metal material 142 deforms inelastically, such that the yield stress of the electroplated metal material 142 is low. The lower yield stress of the electroplated metal material 142 means that less stress is applied to the glass-based substrate 110, which reduces the likelihood of lateral glass fractures. As described herein, a hysteresis loop of greater than or equal to 10,000 MPa° C. may be achieved through a variety of means, including electroplating impurity content, annealing conditions, and/or electroplating current density.

In embodiments, the at least one redistribution layer 140 may comprise greater than or equal to 2 and less than or equal to 10 layers of electroplated metal material 142. For example, the at least one redistribution layer 140 may comprise greater than or equal to 3, greater than or equal to 4, greater than or equal to 5, greater than or equal to 6, greater than or equal to 7, greater than or equal to 8, greater than or equal to 9 and less than or equal to 9, less than or equal to 8, less than or equal to 7, less than or equal to 6, less than or equal to 5, less than or equal to 4, less than or equal to 3, or any and all sub-ranges formed from any of these endpoints. In embodiments, the at least one redistribution layer 140 may comprise greater than or equal to 2 and less than or equal to 10 layers of dielectric material 144. For example, the at least one redistribution layer 140 may comprise greater than or equal to 3, greater than or equal to 4, greater than or equal to 5, greater than or equal to 6, greater than or equal to 7, greater than or equal to 8, greater than or equal to 9 and less than or equal to 9, less than or equal to 8, less than or equal to 7, less than or equal to 6, less than or equal to 5, less than or equal to 4, less than or equal to 3 layers of dielectric material 144, or any and all sub-ranges formed from any of these endpoints.

Each of the layers of electroplated material 142 may comprise a thickness greater than or equal to 0.5 μm and less than or equal to 25 μm. For example, each of the layers of electroplated material 142 may comprise a thickness greater than or equal to 1 μm, greater than or equal to 2 μm, greater than or equal to 4 μm, greater than or equal to 6 μm, greater than or equal to 8 μm, greater than or equal to 10 μm, greater than or equal to 12 μm, greater than or equal to 14 μm, greater than or equal to 16 μm, greater than or equal to 18 μm, greater than or equal to 20 μm, greater than or equal to 22 μm, greater than or equal to 14 μm and less than or equal to 24 μm, less than or equal to 22 μm, less than or equal to 20 μm, less than or equal to 18 μm, less than or equal to 16 μm, less than or equal to 14 μm, less than or equal to 12 μm, less than or equal to 8 μm, less than or equal to 6 μm, less than or equal to 4 μm, less than or equal to 2 μm, less than or equal to 1 μm, or any and all sub-ranges formed from any of these endpoints.

The electroplated metal material 142 may comprise a yield stress less than 200 MPa. For example, the electroplated metal material 142 may comprise a yield stress less than 190 MPa, less than 180 MPa, less than 170 MPa, less than 160 MPa, less than 150 MPa, less than 140 MPa, less than 130 MPa, less than 120 MPa, less than 110 MPa, less than 100 MPa, less than 90 MPa, less than 80 MPa, less than 70 MPa, less than 60 MPa, or less than 50 MPa, or any and all sub-ranges formed from any of these endpoints.

The microelectronic article 100 may comprise a warp less than or equal to 50 μm, as measured at an edge of the microelectronic article 100, when the microelectronic article 100 is 50 mm by 50 mm. For example, the microelectronic article 100 may comprise a warp less than or equal to 45 μm, less than or equal to 40 μm, less than or equal to 35 μm, less than or equal to 30 μm, less than or equal to 25 μm, less than or equal to 20 μm, less than or equal to 15 μm, or less than or equal to 10 μm, as measured at an edge of the microelectronic article 100 when the microelectronic article 100 is 50 mm by 50 mm. In embodiments, the warp, as measured at an edge of the microelectronic article 100 when the microelectronic article 100 is 50 mm by 50 mm, is in a range from 0 μm to 50 μm, from 5 μm to 45 μm, from 10 μm to 40 μm, from 15 μm to 35 μm, from 20 μm to 30 μm, or any and all sub-ranges formed from any of these endpoints.

In embodiments, the microelectronic article may comprise a layer of an adhesion promoter 120, such as titanium. The adhesion promoter 120 may comprise a thickness greater than or equal to 0.02 μm and less than or equal to 0.3 μm. For example, the thickness of the adhesion promoter 120 may be greater than or equal to 0.04 μm, greater than or equal to 0.06 μm, greater than or equal to 0.08 μm, greater than or equal to 0.1 μm, less than or equal to 0.28 μm, less than or equal to 0.26 μm, less than or equal to 0.24 μm, less than or equal to 0.22 μm, less than or equal to 0.2 μm, less than or equal to 0.18 μm, less than or equal to 0.16 μm, or any and all sub-ranges formed from any of these endpoints.

The microelectronic article may comprise a layer of sputtered copper 122. The layer of sputtered copper 122 may comprise a thickness greater than or equal to 0.05 μm and less than or equal to 0.5 μm. For example, layer of sputtered copper 122 may comprise a thickness greater than or equal to 0.08 μm, greater than or equal to 0.1 μm, greater than or equal to 0.12 μm, greater than or equal to 0.14 μm, greater than or equal to 0.16 μm, greater than or equal to 0.18 μm, greater than or equal to 0.20 μm and less than or equal to 0.48 μm, less than or equal to 0.46 μm, less than or equal to 0.44 μm, less than or equal to 0.42 μm, less than or equal to 0.40 μm, less than or equal to 0.38 μm, less than or equal to 0.36 μm, less than or equal to 0.34 μm, less than or equal to 0.32 μm, less than or equal to 0.30 μm, less than or equal to 0.28 μm, less than or equal to 0.26 μm, or any and all sub-ranges formed from any of these endpoints.

In embodiments, the glass-based substrate 110 may comprise a coefficient of thermal expansion (CTE) that is greater than or equal to 0.2×10⁻⁶/° C. and less than or equal to 13×10⁻⁶/° C. over a temperature range of −100° C. to 450° C. In some embodiments, the glass-based substrate 110 may have a CTE greater than or equal to 0.2×10⁻⁶/° C. and less than or equal to 1×10⁻⁶/° C., greater than or equal to 0.2×10⁻⁶/° C. and less than or equal to 12×10⁻⁶/° C., greater than or equal to 0.2×10⁻⁶/° C. and less than or equal to 10×10⁻⁶/° C., greater than or equal to 0.2×10⁻⁶/° C. and less than or equal to 8×10⁻⁶/° C., greater than or equal to 0.2×10⁻⁶/° C. and less than or equal to 6×10⁻⁶/° C., greater than or equal to 0.2×10⁻⁶/° C. and less than or equal to 4×10⁻⁶/° C., greater than or equal to 0.2×10⁻⁶/° C. and less than or equal to 2×10⁻⁶/° C., greater than or equal to 0.5×10⁻⁶/° C. and less than or equal to 13×10⁻⁶/° C., greater than or equal to 1×10⁻⁶/° C. and less than or equal to 13×10⁻⁶/° C., greater than or equal to 2×10⁻⁶/° C. and less than or equal to 13×10⁻⁶/° C., greater than or equal to 4×10⁻⁶/° C. and less than or equal to 13×10⁻⁶/° C., greater than or equal to 6×10⁻⁶/° C. and less than or equal to 13×10⁻⁶/° C., greater than or equal to 8×10⁻⁶/° C. and less than or equal to 13×10⁻⁶/° C., greater than or equal to 10×10⁻⁶/° C. and less than or equal to 13×10⁻⁶/° C., greater than or equal to 12×10⁻⁶/° C. and less than or equal to 13×10⁻⁶/° C., or any and all sub-ranges formed from any of these endpoints, over a temperature range of −100° C. to 450° C. The methods for making microelectronic articles described herein decrease the likelihood for glass fractures, regardless of the CTE of the glass-based substrate 110.

The glass-based substrate 110 may comprise an elastic modulus that is greater than or equal to 50 GPa and less than or equal to 200 GPa. For example, in some embodiments, the glass-based substrate 110 may have an elastic modulus greater than or equal to 50 GPa and less than or equal to 200 GPa, greater than or equal to 75 GPa and less than or equal to 200 GPa, greater than or equal to 100 GPa and less than or equal to 200 GPa, greater than or equal to 125 GPa and less than or equal to 200 GPa, greater than or equal to 50 GPa and less than or equal to 175 GPa, greater than or equal to 50 GPa and less than or equal to 150 GPa, greater than or equal to 50 GPa and less than or equal to 125 GPa, greater than or equal to 50 GPa and less than or equal to 100 GPa, greater than or equal to 50 GPa and less than or equal to 75 GPa, greater than or equal to 75 GPa and less than or equal to 175 GPa, greater than or equal to 100 GPa and less than or equal to 150 GPa, or any and all sub-ranges formed from any of these endpoints.

The glass-based substrate 110 may comprise a thickness greater than or equal to 100 μm and less than or equal to 1000 μm. For example, in some embodiments, the glass-based substrate 110 may have a thickness that is greater than or equal to 150 μm and less than or equal to 1000 μm, greater than or equal to 200 μm and less than or equal to 1000 μm, greater than or equal to 250 μm and less than or equal to 1000 μm, greater than or equal to 300 μm and less than or equal to 1000 μm, greater than or equal to 350 μm and less than or equal to 1000 μm, greater than or equal to 400 μm and less than or equal to 1000 μm, greater than or equal to 450 μm and less than or equal to 1000 μm, greater than or equal to 500 μm and less than or equal to 1000 μm, greater than or equal to 550 μm and less than or equal to 1000 μm, greater than or equal to 600 μm and less than or equal to 1000 μm, greater than or equal to 650 μm and less than or equal to 1000 μm, greater than or equal to 700 μm and less than or equal to 1000 μm, greater than or equal to 750 μm and less than or equal to 1000 μm, greater than or equal to 800 μm and less than or equal to 1000 μm, greater than or equal to 850 μm and less than or equal to 1000 μm, greater than or equal to 900 μm and less than or equal to 1000 μm, greater than or equal to 950 μm and less than or equal to 1000 μm, greater than or equal to 100 μm and less than or equal to 950 μm, greater than or equal to 100 μm and less than or equal to 900 μm, greater than or equal to 100 μm and less than or equal to 850 μm, greater than or equal to 100 μm and less than or equal to 800 μm, greater than or equal to 100 μm and less than or equal to 750 μm, greater than or equal to 100 μm and less than or equal to 700 μm, greater than or equal to 100 μm and less than or equal to 650 μm, greater than or equal to 100 μm and less than or equal to 600 μm, greater than or equal to 100 μm and less than or equal to 550 μm, greater than or equal to 100 μm and less than or equal to 500 μm, greater than or equal to 100 μm and less than or equal to 450 μm, greater than or equal to 100 μm and less than or equal to 400 μm, greater than or equal to 100 μm and less than or equal to 350 μm, greater than or equal to 100 μm and less than or equal to 300 μm, greater than or equal to 100 μm and less than or equal to 250 μm, greater than or equal to 150 μm and less than or equal to 950 μm, greater than or equal to 200 μm and less than or equal to 900 μm, greater than or equal to 250 μm and less than or equal to 850 μm, greater than or equal to 300 μm and less than or equal to 800 μm, greater than or equal to 350 μm and less than or equal to 750 μm, greater than or equal to 400 μm and less than or equal to 700 μm, or any and all sub-ranges formed from any of these endpoints. The thickness of the glass-based substrate 110 refers to the distance extending from the first surface 112 to the second surface 114. As described herein, thickness of the glass-based substrate 110 may be measured by using a micrometer gauge.

### EXAMPLES

In order that various embodiments be more readily understood, reference is made to the following examples, which are intended to illustrate various embodiments of the microelectronic articles and methods of making the same according to embodiments described herein.

### Preparation of Comparative and Inventive Microelectronic Articles

Referring now to FIG. 2A, the structure of Comparative Examples CA and CB is shown. The structure of Comparative Examples CA and CB includes a glass substrate 110 having a thickness of 500 μm. A titanium adhesion promoter layer 120 having a thickness of 0.1 μm was disposed on the glass substrate 110, followed by a sputtered copper layer 122 with a thickness of 0.2 μm. The titanium layer 120 and sputtered copper layer 122 were deposited at 200° C. All samples were 50 mm by 50 mm in size. The structure of Comparative Examples CA and CB are one-sided, such that the structure comprises a film (i.e., the titanium layer 120 and the sputtered copper layer 122) on one surface of the glass substrate 110.

Referring now to FIG. 2B, the structure of Comparative Example CC and Inventive Examples 11, 12, and 13 is shown. The structure of Comparative Example CC and Inventive Examples 11-13 included a glass substrate 110 along with the same adhesion promoter layer 120 and sputtered copper layer 122 as described herein with respect to FIG. 2A. The structure of Inventive Examples I1 and I2 further included electroplating a layer of copper 142 having a thickness of 3 μm onto the sputtered copper layer 122 at room temperature (i.e., around 23° C. to 25° C.) using a LPKF 400 commercial copper plating bath. All samples were 50 mm by 50 mm in size. The structure of Comparative Example CC and Inventive Examples 11-13 are one-sided, such that the structure comprises a film (i.e., the titanium layer 120, the sputtered copper layer 122, and the electroplated copper layer 142) on one surface of the glass substrate 110.

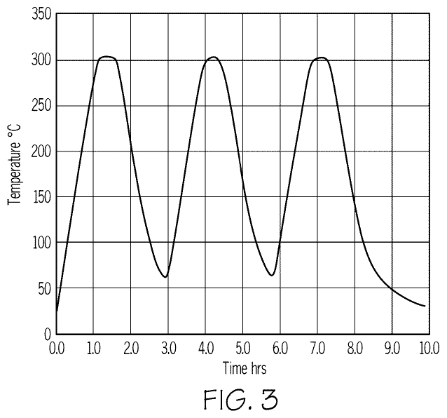

For samples with an electroplated copper layer 142, the sample was subjected to repeated thermal cycling using a FLX 2320-S system to a peak temperature of 300° C. using a ramp rate of 4° C./min. The sample was held at 300° C. for 30 min before cooling down to a temperature of 30° C. Three cycles were performed on each sample. FIG. 3 shows a temperature profile of the thermal cycling performed on the samples. Based on the change in radius curvature as a function of temperature, the in-plane film stress was determined.

### Glass Compositions

Two types of glass compositions, G1 and G2, were used in the examples. The composition and properties of both glass compositions are shown in Table 1.

TABLE 1

| | G1 | G2 |
|---|---|---|
| SiO₂ (mol. %) | 67.53 | 67.52 |
| Al₂O₃ (mol. %) | 12.68 | 11.05 |
| B₂O₃ (mol. %) | 3.68 | 9.82 |
| Na₂O (mol. %) | 13.67 | — |
| K₂O (mol. %) | 0.01 | — |
| MgO (mol. %) | 2.33 | 2.26 |
| CaO (mol. %) | — | 8.76 |
| SrO (mol. %) | — | 0.5 |
| SnO₂ (mol. %) | 0.1 | 0.08 |
| Fe₂O₃ (mol. %) | 0.01 | — |
| Elastic Modulus (GPa) | 69.3 | 73.6 |
| CTE (/° C.) | 7.58 × 10⁻⁶ | 3.17 × 10⁻⁶ |
| Elastic Modulus × CTE (GPa/° C.) | 5.24 × 10⁻⁴ | 2.33 × 10⁻⁴ |
| CTE_{Cu} − CTE_{G} (/° C.) | 9.12 × 10⁻⁶ | 1.35 × 10⁻⁵ |
| Glass Thickness (μm) | 500 | 500 |

The elastic film stress was calculated for each of the Comparative Examples CA and CB and the Inventive Examples I1 and I2. Elastic film stress (σ_{f}) is the force per unit area that causes deformation in the glass substrates and may be caused due to different CTE values (such as the different CTE values between glass-based substrate 110 and RDL 140. For purposes of the present disclosure, elastic film stress is calculated using Formula (II) below, where T₀ is the reference temperature and T is the peak temperature. The calculation of Formula (I) assumes T₀ is 30° C., T is 300° C., E_{f} (the elastic modulus of copper) is 210 GPa, V_{f} (Poisson ratio of copper) is 0.33, and α_{f} (CTE of copper) is 16.7×10⁻⁶/° C. Values for the CTE glass compositions G1 and G2 (αₛ) were taken from Table 1. The calculation revealed that the deposition of copper on a glass substrate comprising G2 resulted in a 1.5 times higher elastic film stress (σ_{f}) as compared to the deposition of copper on a glass substrate comprising G1 due to the greater CTE mismatch between materials.

$${σ}_{f} = ( {α}_{f} - {α}_{s} ) ( T - {T}_{0} ) ( \frac{{E}_{f}}{1 - {V}_{f}} ) \qquad ( II )$$

### Glass Substrate Compositions

Referring now to Table 2, Comparative Examples CA and CB and Inventive Examples I1 and I2 were formed using the glass compositions indicated in Table 2 to make the glass substrate. The elastic film stress of each sample (as calculated using Formula (II) above) is also provided in Table 2.

TABLE 2

| | CA | CB | I1 | I2 |
|---|---|---|---|---|
| Glass Composition | G1 | G2 | G1 | G2 |
| Elastic Film Stress (MPa) | 102.7 ± | 288.1 ± | 119 ± | 127 ± |
| | 56.3 | 48.2 | 13.5 | 10.1 |
| Difference in Elastic Film | — | 185.4 | — | 6.0 |
| Stress (MPa) | | | | |

In Table 2 above, the difference in elastic film stress is the difference between Comparative Examples CA and CB and the difference between Inventive Examples I1 and I2. As shown in Table 2, Comparative Examples CA and CB, articles without an electroplated copper layer, had a relatively large difference in elastic film stress of 185.4 MPa. Comparative Example CB, which included glass composition G2, had almost a three times increase in elastic film stress as compared to Comparative Example CA, which included glass composition G1. This was to be expected due to the relatively higher difference in the CTE of copper and the CTE of glass composition G2, as compared to the relatively smaller difference of the CTE of copper and the CTE of glass composition G1.

Referring again to Table 2, Inventive Examples I1 and I2, articles having an electroplated copper layer, had a relatively small difference in elastic film stress of 6.0 MPa. As exemplified by Table 2, making a microelectronic article according to the methods described herein, including electroplating, may minimize the effects of CTE mismatch between copper and glass, regardless of the glass composition.

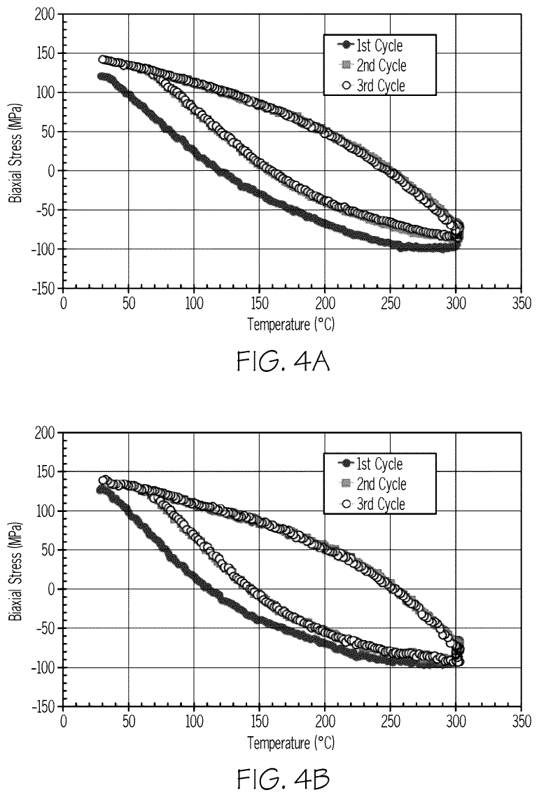

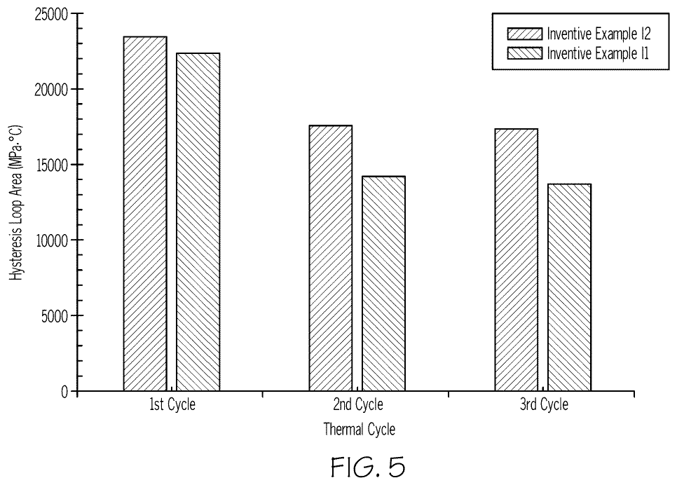

Referring now to FIGS. 4A and 4B, the stress-temperature curves of Inventive Example I1 and Inventive Example I2, respectively, are shown. Inventive Example I1 includes glass composition G1 and Inventive Example I2 includes glass composition G2. The stress-temperature curve shows how the electroplated copper material responds upon subjection to the three thermal cycles as shown in FIG. 3, described above. As shown in FIGS. 4A and 4B, the stress-temperature curves of the 2^{nd} and 3^{rd} cycles are substantially similar, such that they appear to overlap. As shown in FIG. 5, the difference between the area of the hysteresis loops of Inventive Examples I1 and I2 were relatively small, particularly for the first cycle. The largest difference was in the third cycle, where the area of the hysteresis loop of Inventive Example I2 was 22% larger than the area of the hysteresis loop of Inventive Example I1. As exemplified by FIGS. 4A, 4B, and 5, the glass composition of the glass substrate has a minimal effect on the area of the hysteresis loop of the electroplated metal material according to the methods described herein.

### Electroplated Copper Impurity Content Level

Comparative Example CC and Inventive Example I3 were formed using the glass composition G2 to make the glass-based substrate. Comparative Example CC and Inventive Example I3 comprised the same structure and method to produce as that described above with reference to Inventive Examples 12. But Comparative Example CC further comprised a high impurity electroplated copper layer and Inventive Example I3 comprised a low impurity electroplated copper layer. Comparative Example CC comprised an electroplated copper layer having an impurity content greater than 1000 ppmw. Inventive Example I3 comprised an electroplated copper layer having an impurity content less than or equal to 1000 ppmw.

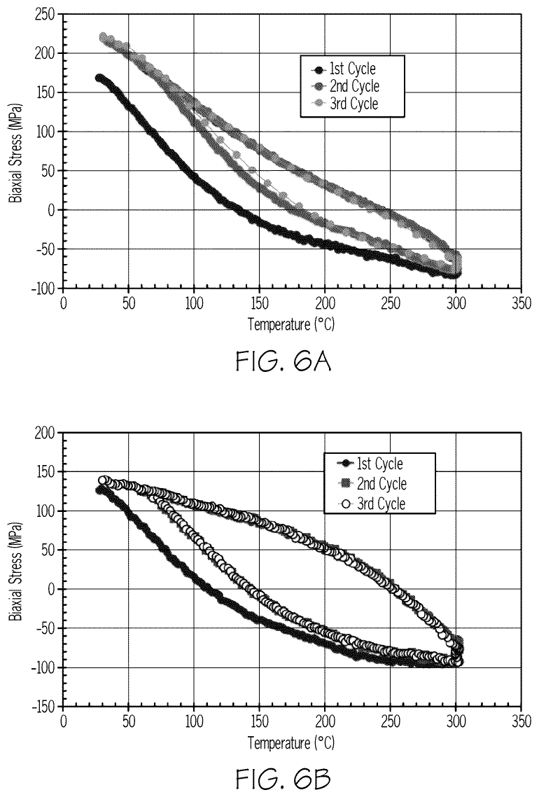

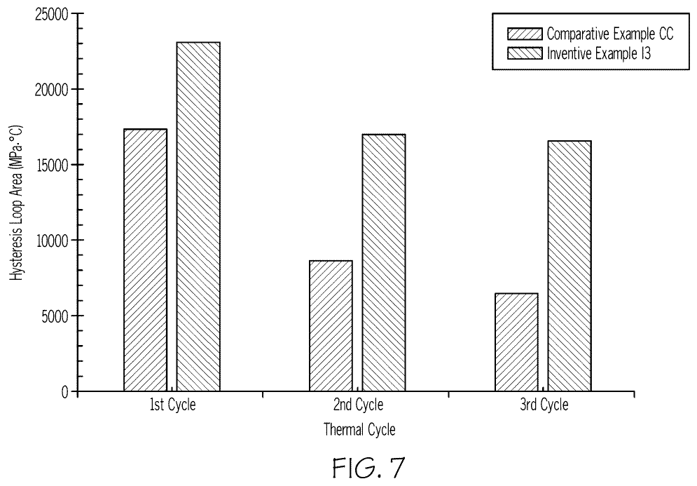

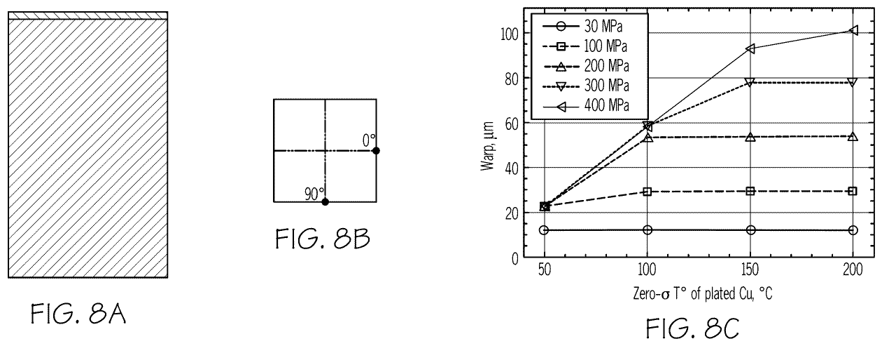

Referring now to FIGS. 6A and 6B, the stress-temperature curves of Comparative Example CC and Inventive Example I3, respectively, are shown. As shown in FIG. 6A, the electroplated copper layer of Comparative Example CC having a high impurity content resulted in a stress-temperature curve with a relatively narrow hysteresis loop. A peak stress of 220 MPa is shown at 30° C. As shown in FIG. 6B, the electroplated copper layer of Inventive Example I3 with a low impurity content resulted in a stress-temperature curve with a much wider hysteresis loop. A peak stress of 140 MPa was determined at 30° C. Using a low impurity content copper as in Inventive Example I3 led to a 36% reduction in the film stress as compared to using a high impurity content copper as in Comparative Example CC.

The areas of the hysteresis loops in FIGS. 6A and 6B are depicted in FIG. 7. For all three cycles, the area of the hysteresis loop of Inventive Example I3, including low impurity content electroplated copper, was larger than the area of the hysteresis loop of Comparative Example CC, including high impurity content electroplated copper. The area of the hysteresis loop of Inventive Example I3 was 60% larger than the area of the hysteresis loop of Comparative Example CC. As exemplified by FIGS. 6A, 6B, and 7, making a microelectronic article according to the methods described herein using a low impurity content copper may result in a microelectronic article having a relatively large hysteresis loop area.

### Glass Substrate Warpage

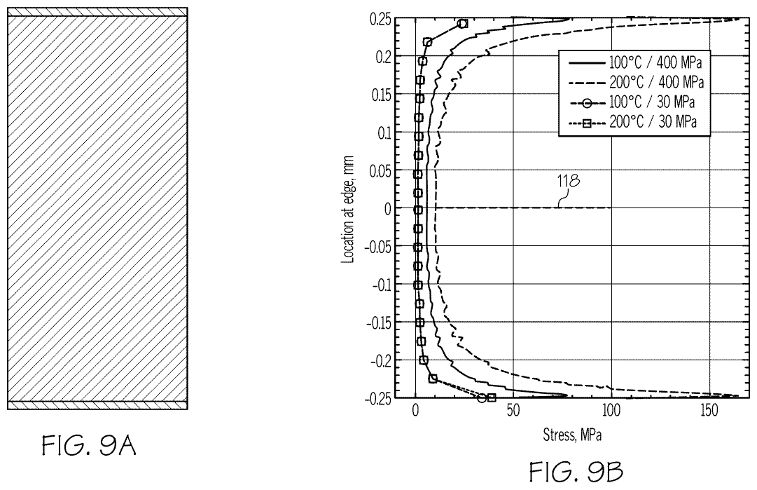

A 2D axisymmetric finite element model was developed to evaluate warpage in a microelectronic article sample with one redistribution layer (FIG. 8A) and lateral fracture likelihood in a microelectronic article sample with two redistribution layers (FIG. 9A). Each sample comprised a 50×50×0.5 mm glass substrate (elastic modulus (E)=74 GPa, CTE=3.2 ppm/° C., v=0.2). Each redistribution layer comprised a 100 nm titanium adhesion layer (E=170 GPa, CTE=8.4 ppm/° C., v=0.33), a 200 nm copper seed layer (E=117.7 GPa, CTE=17.2 ppm/° C., v=0.34), and a 3 μm electroplated copper layer. The one-sided sample had one redistribution layer disposed on the first surface of the glass substrate. The two-sided sample had two redistribution layers, one disposed on the first surface of the glass substrate and the other disposed on the second surface of the glass substrate. The microelectronic article with two redistribution layers was symmetric with respect to the midplane 118, as shown in FIG. 9B.

In both samples, the titanium and copper seed layers were deposited on the glass substrate at 200° C., but assumed to have no stress at 135° C. Thus, the zero-stress temperatures of titanium and copper seed layers were assumed to be 135° C. The electroplated copper was assumed to be varied, so modeling was performed with electroplated copper zero-stress temperatures of 50° C., 100° C., 150° C., and 200° C.

FIG. 8A depicts a schematic side-view of the one-sided sample, as described above. FIG. 8B depicts warp output of the sample FIG. 8A. FIG. 8C shows a plot of warp versus zero-stress temperature of the electroplated copper. A higher yield stress correlates with a more elastic copper. A higher zero-stress temperature correlates with a higher potential to warp. As shown in FIG. 8C, a yield stress of 100 MPa compared to 200 MPa for electroplated copper with zero-stress temperatures above 100° C. decreases the warp from around 53 μm to around 30 μm, almost a factor of 2. As exemplified by FIGS. 8A, 8B, and 8C, electroplated copper with a yield stress of less than 200 MPa may decrease the warp of the microelectronic article.

FIG. 9A depicts a schematic side-view of the two-sided sample, as described above. FIG. 9B depicts a plot of the distribution of stress along the edge of the glass substrate for modeled samples with varying zero-stress temperatures and yield stresses. As shown in FIG. 9B, a more elastic electroplated copper (i.e. yield stress of 400 MPa) had a higher stress along the entire edge of the glass. When the electroplated copper yield stress was low (i.e., 30 MPa), the stress profiles for 100° C. and 200° C. zero-stress temperatures were similar. Stresses in the glass at the midplane 118 exhibited a similar trend as those at the edges, where the high yield stress and high zero-stress temperature of the copper resulted in a greater stress in the glass.

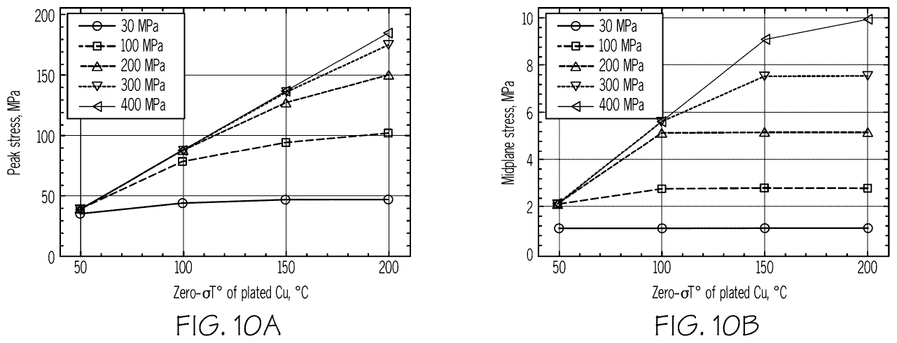

FIG. 10A depicts a plot of peak stress at the corners of the glass substrate edge versus zero-stress temperature. As shown in FIG. 10A, a lower yield stress of the electroplated copper resulted in a lower peak stress at the corners of the glass substrate edge across varied zero-stress temperatures. As exemplified by FIG. 10A, utilizing an electroplated copper with a lower yield stress may minimize the likelihood of fractures at the glass substrate edge.

FIG. 10B depicts a plot of stress at the midplane of the glass substrate versus zero-stress temperature. As shown in FIG. 10B, a lower yield stress of the electroplated copper resulted in a lower midplane stress across varied zero-stress temperatures. As exemplified by FIG. 10B, utilizing an electroplated copper with a lower yield stress may minimize the likelihood of lateral fractures within the glass substrate, such as at the midplane of the glass substrate.

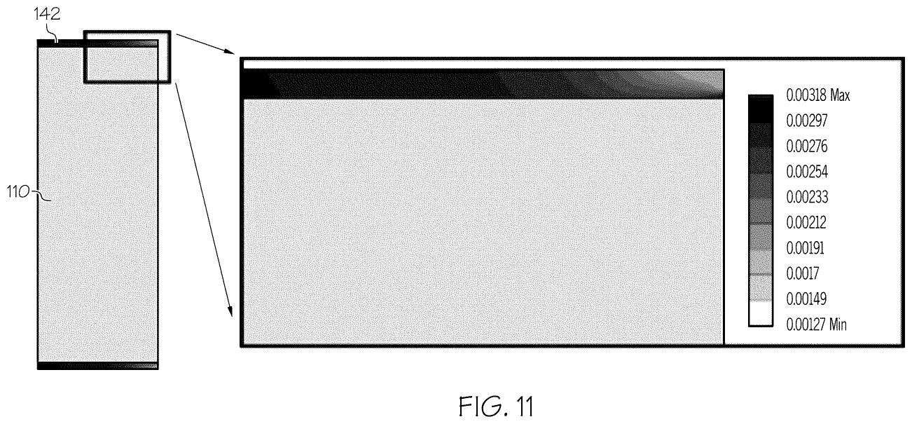

FIG. 11 depicts a model of plastic strain distribution in a sample comprising a glass substrate 110 with a layer of electroplated copper 142 having a thickness of 3 μm that has a zero-stress temperature of 150° C. and a yield stress of 100 MPa after annealing. As shown in FIG. 11, the corners of the glass substrate edge had a decreased yield stress. As exemplified by FIG. 11, utilizing an electroplated copper with a low yield stress may minimize the likelihood of fractures within the glass substrate, such as at the corners of the glass substrate.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A microelectronic article comprising:
a glass-based substrate and at least one redistribution layer disposed on the glass-based substrate, wherein:
the at least one redistribution layer comprises an electroplated metal material and a dielectric material; and
the electroplated metal material comprises a hysteresis loop greater than or equal to 10,000 MPa·° C.

2. The microelectronic article of claim 1, wherein the at least one redistribution layer further comprises an adhesion promoter.

3. The microelectronic article of claim 1, wherein the electroplated metal material comprises copper, aluminum, aluminum-copper, or a combination thereof.

4. The microelectronic article of claim 1, wherein the electroplated metal material is patterned.

5. The microelectronic article of claim 1, wherein the dielectric material comprises polyimide, polybenzoxazoles, polyolefin, polystyrene, epoxy resins, parylene, benzocyclobutene, ring-opened norbornen type polymers, or combinations thereof.

6. The microelectronic article of claim 1, further comprising a metallized through glass via.

7. The microelectronic article of claim 1, wherein:
the glass-based substrate comprises a first surface and a second surface;
a first redistribution layer disposed on the first surface; and
a second redistribution layer disposed on the second surface.

8. The microelectronic article of claim 1, wherein the at least one redistribution layer comprises greater than or equal to 2 and less than or equal to 10 layers of the electroplated metal material, each of the layers of the electroplated material comprising a thickness greater than or equal to 0.5 μm and less than or equal to 25 μm.

9. The microelectronic article of claim 1, wherein the electroplated metal material comprises a yield stress less than 200 MPa.

10. The microelectronic article of claim 1, wherein the microelectronic article comprises a warp less than or equal to 50 μm, as measured at an edge of the microelectronic article, when the microelectronic article is 50 mm by 50 mm.

11. The microelectronic article of claim 1, wherein the electroplated metal material comprises an impurity content less than or equal to 1000 ppmw.

12. The microelectronic article of claim 1, wherein the glass-based substrate has a coefficient of thermal expansion greater than or equal to 0.2×10⁻⁶/° C. and less than or equal to 13×10⁻⁶/° C.

13. The microelectronic article of claim 1, wherein the glass-based substrate comprises a thickness greater than or equal to 100 μm and less than or equal to 1000 μm.

14. The microelectronic article of claim 1, wherein the at least one redistribution layer comprises a thickness greater than or equal to 500 nm.

15. A method of making a microelectronic article, the method comprising:
depositing at least one redistribution layer on a glass-based substrate, wherein the depositing the at least one redistribution layer comprises at least one cycle of:
electroplating the glass-based substrate with a metal material to form an electroplated metal material;
annealing the glass-based substrate and the electroplated metal material at a ramp rate greater than or equal to 0.5° C./min and less than or equal to 10° C./min to a peak temperature greater than or equal to 200° C. and less than or equal to 400° C.; and
disposing a dielectric material at least one of on or between the electroplated metal material,
wherein the electroplated metal material comprises a hysteresis loop greater than or equal to 10,000 MPa·° C.

16. A method of making a microelectronic article, the method comprising:
depositing at least one redistribution layer on a glass-based substrate, wherein the depositing the at least one redistribution layer comprises at least one cycle of:
electroplating the glass-based substrate with a metal material to form an electroplated metal material, wherein the electroplated metal material has an impurity content of less than or equal to 1000 parts per million by weight (ppmw); and
disposing a dielectric material at least one of on or between the electroplated metal material,
wherein the electroplated metal material comprises a hysteresis loop greater than or equal to 10,000 MPa·° C.

17. The method of claim 16, wherein the metal material comprises copper, aluminum, aluminum-copper, or a combination thereof.

18. The method of claim 16, wherein the dielectric material comprises polyimide, polybenzoxazoles, polyolefin, polystyrene, epoxy resins, parylene, benzocyclobutene, ring-opened norbornen type polymers, or combinations thereof.

19. The method of claim 16, wherein the glass-based substrate has a coefficient of thermal expansion greater than or equal to 0.2×10⁻⁶/° C. and less than or equal to 13×10⁻⁶/° C.

20. The method of claim 16, wherein the electroplated metal material comprises a yield stress less than 200 MPa.
